(19) United States
(12) Patent Application Publication
(10) Pub. No.: US 2010/0127731 A1
(43) Pub. Date: May 27, 2010

(54) Antifuse circuit of inverter type and method of programming the same

(75) Inventors: Jae-Yong Seo, Hwaseong-si (KR); Gu-Gwan Kang, Uiwang-si (KR); Tae-Hun Kang, Yongin-si (KR); Hong-Sik Park, Suwon-si (KR); Jung-Hyeon Kim, Hwaseong-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/585,276

(22) Filed: Sep. 10, 2009

(30) Foreign Application Priority Data
Nov. 27, 2008 (KR) 10-2008-0118615

(51) Int. Cl. H03K 19/173; H01H 37/76

(52) U.S. Cl. 326/37; 327/525

(57) ABSTRACT

Example embodiments are directed to an antifuse circuit of an inverter type and a method of programming the same. The antifuse circuit has improved corrosion resistance, utilizes lesser chip area and can be programmed at a low voltage. The antifuse circuit includes a PMOS transistor with the gate coupled to a drive power voltage terminal and the source coupled to an anti-pad terminal. During programming the PMOS transistor is off and the source receives an alternating current. Programming the antifuse circuit involves trapping a plurality of electron in an STI region as a result of gate-induced drain leakage. The antifuse circuit also includes an NMOS transistor with the drain connected to the drain of the PMOS transistor, the source connected to ground and the gate connected to a program control signal. The antifuse circuit results in reliable fuse programming at a low voltage by using the PMOS transistor as an anti-fuse device.

### FOREIGN PRIORITY STATEMENT

This application claims priority under 35 U.S.C. §119 to Korean Patent Application 10-2008-0118615 filed on Nov. 27, 2008, in the Korean Intellectual Property Office (KIPO), the entire contents of which are incorporated herein by reference.

### BACKGROUND

1. Field

Example embodiments relate to antifuse circuits, for example, an antifuse circuit of an inverter type for use in a semiconductor memory device such as a dynamic random access memory (DRAM) or the like and the method of programming the same.

2. Description of the Related Art

Generally, because of user and other requirements, speed and device integration of semiconductor memory devices, such as, DRAM, is steadily increasing. Electronic systems may implement a DRAM device, having one access transistor and one storage capacitor as a unit memory cell, as the main memory of the electronic system.

DRAM employed in a general data processing system may be coupled to a micro-processing unit or a control unit using a system bus and may function as the main device memory. Such a micro-processing unit or control unit of the data processing system may also be coupled to a flash memory using a system bus and may control a drive unit based on a program stored in the flash memory. In controlling the drive unit, the micro-processing unit may perform a variety of data access operations including, for example, a write operation for writing data to a memory cell of the DRAM and a read operation for reading data from a memory cell.

In the DRAM, fuse devices storing required-information separately from a memory cell are employed for a redundancy operation of replacing a defective cell with a spare cell or for an operation necessary just in a test or mode selection necessary for an internal data access operation.

FIG. 1 illustrates an example circuit of a conventional fuse. The conventional fuse shown in FIG. 1 is referred to as a poly-fuse when it is formed of a polysilicon material. The conventional fuse is referred to as a laser fuse if the fuse is melted (e.g. blown) using a laser. The conventional fuse may also be referred to as an e-poly fuse when a portion of the fuse between a cathode and an anode is blown and/or melted by electromigration effect of charge carriers due to supply of an over current.

As illustrated in FIG. 1, a number of laser fuses may be included in a fuse box covered with an insulation layer. During programming the laser fuses contained in the fuse box are opened. The opened fuses may be relatively weak to an external influence in comparison to other portions of a chip. Thus, defects due to corrosion from moisture or due to residue particles from using a laser to blow the fuse may occur.

FIG. 2 illustrates an example cross-section of a conventional antifuse and also illustrates a circuit using the conventional antifuse. As shown in FIG. 2, the antifuse used in the circuit functions based on a breakdown of insulation layer, for example, a gate oxide layer or a cap oxide layer. In FIG. 2, MC represents a metal contact, BC represents a butting contact, SP represents a storage polysilicon, and PP represents a plate polysilicon.

Some or all the various fuse structures mentioned above operate based on a programming voltage Vpgm, programming current Ipgm and a program time appropriate for the respective fuse structures.

FIG. 3 illustrates the example antifuse circuit of FIG. 2 in relative detail. The antifuse circuit of FIG. 3 includes a fuse program signal drive unit including PMOS transistors P1, P2 and P3, NMOS transistors N4 and N5, and an inverter IN1 coupled to an NMOS transistor N3. FIG. 3 also includes a fuse circuit including a capacitor C1 and NMOS transistors N1 and N2.

FIG. 4 illustrates a portion of the antifuse circuit of FIG. 3, particularly, the fuse circuit portion of FIG. 3. The fuse circuit shown in FIG. 4 has a fuse structure that may resolve a defect due to moisture absorption caused in the structure of FIG. 1. However, in the fuse circuit of FIG. 4, the capacitor C1 may be manufactured using a cap oxide or gate oxide coupled to an anti-pad through a metal contact, which may cause an increase in chip area.

As a result, the antifuse circuit of FIG. 4 occupied a larger area when used as a fuse in a fuse box.

### SUMMARY

Example embodiments are directed to an antifuse circuit of an inverter type that may include a PMOS transistor with a gate terminal connected to a drive power voltage terminal and a source terminal connected to an anti-pad terminal.

During a fuse programming operation, the PMOS transistor may be turned off and the source terminal of the PMOS transistor may receive a pulse signal. The fuse programming operation may trap a plurality of electrons in a shallow trench isolation (STI) region as a result of gate-induced drain leakage.

The antifuse circuit may also include an NMOS transistor with a drain terminal connected to a drain of the PMOS transistor, a source terminal connected to ground and a gate terminal connected to a program control signal.

According to example embodiments, the pulse signal may be a low voltage alternating current (AC) pulse of around 4V or less and may have a frequency of about 1 MHz to several GHz

According to other example embodiments, the pulse signal may be a low voltage pulse signal that may be varied from about 0V to about 4V and may have a frequency of about 1 MHz.

According to example embodiments, a plurality of sub-STI regions may be formed in a channel region of the PMOS transistor.

According to example embodiments, the drive power voltage applied to the gate terminal of the PMOS transistor may be lower than an internal operating power voltage and the program control signal may be an address signal or selection signal.

According to example embodiments, the antifuse circuit of an inverter type may be included in a semiconductor device.

A method of programming an antifuse circuit of an inverter type, according to example embodiments may include turning off a PMOS transistor of the antifuse circuit, applying an alternating current (AC) pulse signal to a source terminal of the PMOS transistor; and trapping a plurality of electrons in a shallow trench isolation (STI) region of the PMOS transistor as a result of gate-induced drain leakage.

According to example embodiments, the applied AC signal may be of a low voltage that may vary from about 0V to about 4V and may have a frequency of about 1 MHz.

According to example embodiments, a voltage lower than an internal operating power voltage may be applied to the gate terminal of the PMOS transistor to turn off the PMOS transistor.

### BRIEF DESCRIPTION OF THE DRAWINGS

The above and other features and advantages of example embodiments will become more apparent by describing in detail example embodiments with reference to the attached drawings. The accompanying drawings are intended to depict example embodiments and should not be interpreted to limit the intended scope of the claims. The accompanying drawings are not to be considered as drawn to scale unless explicitly noted.

FIG. 1 illustrates a conventional art laser fuse or a poly-fuse contained in a fuse circuit;

FIG. 2 illustrates a cross-section view of a conventional antifuse contained in an example antifuse circuit;

FIG. 3 illustrates the example circuit of FIG. 2 in relative detail;

FIG. 4 illustrates the fuse circuit portion of the antifuse circuit of FIG. 3;

FIG. 5 illustrates an example embodiment of an inverter type antifuse circuit;

FIG. 6 illustrates a conventional method of programming an antifuse;

FIG. 7 illustrates an example method of programming the inverter type antifuse circuit of FIG. 5;

FIG. 8 compares a trapping effect observed in the STI electron trap due to the example programming method shown in FIG. 7 with a trapping effect observed in the STI electron trap due to the conventional programming method;

FIG. 9 shows graphs comparing the voltage-current (VI) characteristics of the STI electron trap of the example embodiment of FIG. 7 with the VI characteristics of a conventional art STI electron trap; and

FIG. 10 illustrates the STI regions in a channel region of PMOS transistor of the example inverter type antifuse circuit shown in FIG. 5.

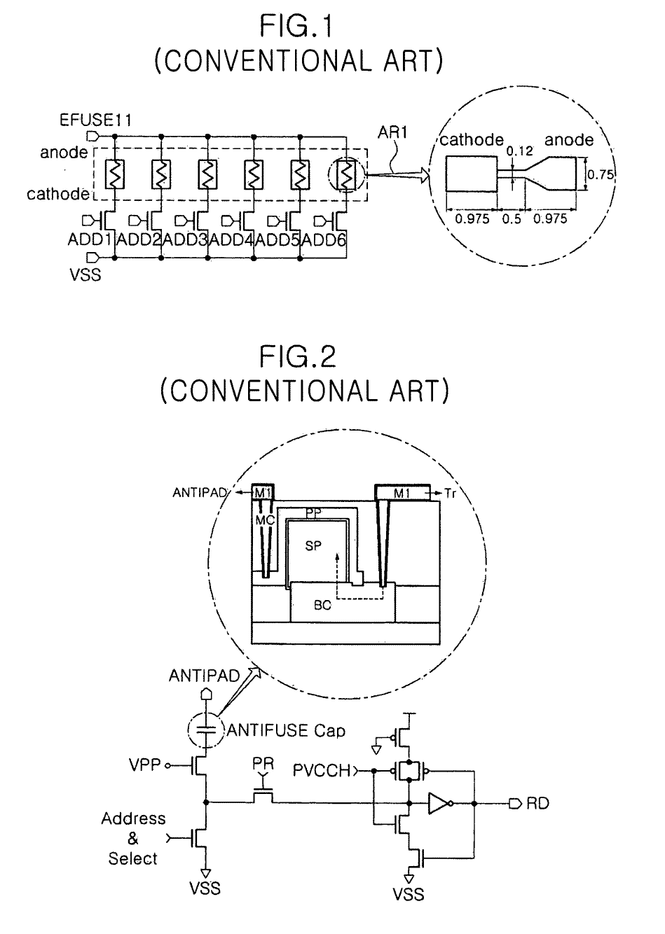

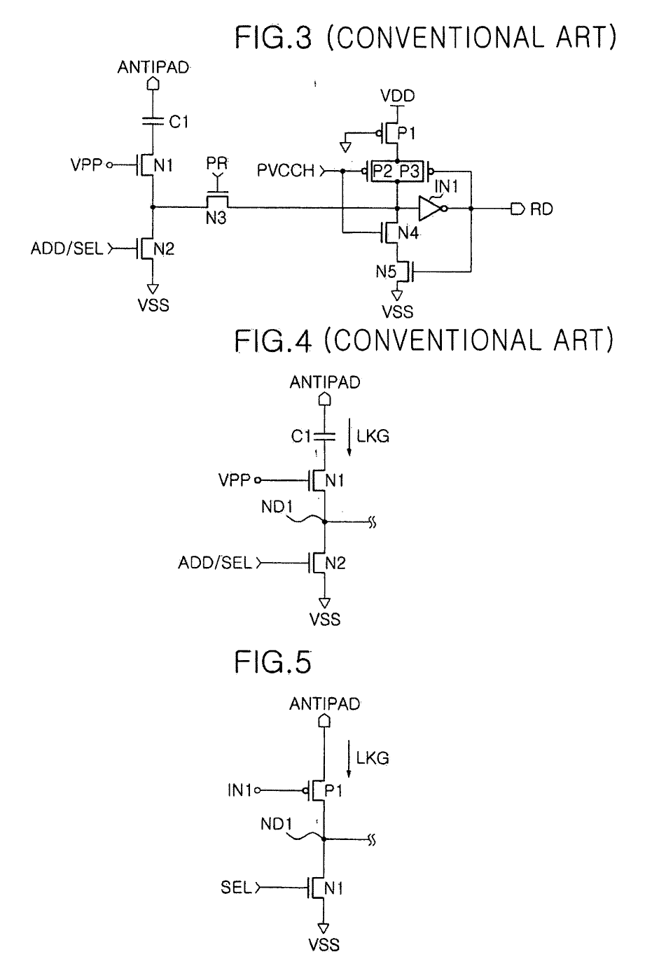

### DETAILED DESCRIPTION OF EXAMPLE EMBODIMENTS

Detailed example embodiments are disclosed herein. However, specific structural and functional details disclosed herein are merely representative for purposes of describing example embodiments. Example embodiments may, however, be embodied in many alternate forms and should not be construed as limited to only the embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but to the contrary, example embodiments are to cover all modifications, equivalents, and alternatives falling within the scope of example embodiments. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

FIG. 5 illustrates an inverter type antifuse circuit according to an example embodiment.

Referring to FIG. 5, the inverter type antifuse circuit may include a PMOS transistor P1 and an NMOS transistor N1. In the inverter type antifuse circuit of FIG. 5, a programming operation is implemented using a shallow trench isolation (STI) trap scheme using gate-induced drain leakage. In FIG. 5, a gate of the PMOS transistor P1 is connected to a drive power voltage terminal IN1 and a source of the PMOS transistor is connected to an anti-pad terminal. A drain of the NMOS transistor N1 is connected to a drain of the PMOS transistor, a source of the NMOS transistor N1 is connected to a ground voltage VSS, and a gate of the NMOS transistor N1 receives a program control signal SEL. As illustrated in FIG. 7, during programming, the PMOS transistor P1 may receive a high frequency alternating current (AC) pulse at the source while the PMOS transistor P1 is in an off state.

A high voltage VPP of around 4V may be applied to the drive power voltage terminal IN1. The high voltage VPP may be lower than an internal operating voltage of the antifuse circuit. The program control signal SEL may be an address signal or selection signal.

Depending on the programming of the PMOS transistor P1, which functions as a fuse device, a high or low signal may be output on an output node ND1. Fuse programming traps electrons in a STI region that defines the formation area of the PMOS transistor P1. The electrons are trapped in the STI region as a result of gate-induced drain leakage mentioned above.

FIG. 7 illustrates an example method of programming the inverter type antifuse circuit of FIG. 5. According to the example method, relatively more electrons may be trapped in the STI region due to the high frequency AC pulse signal applied at the anti-pad as illustrated in FIG. 7.

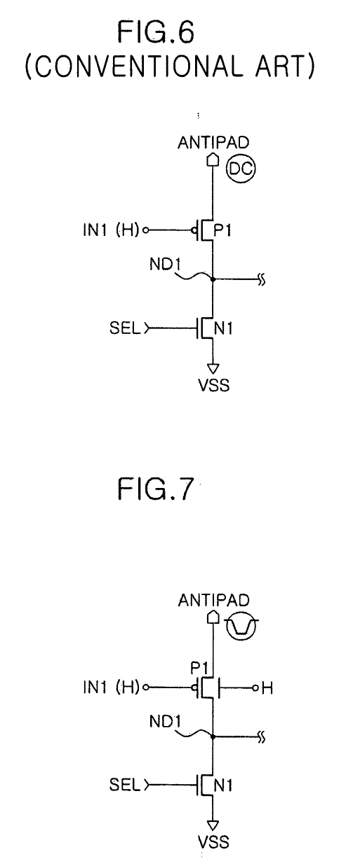

The high frequency AC pulse signal may have a low voltage, approximately 4V or below, and a frequency approximately in a range of 1 megahertz (MHz) to several gigahertz (GHz). Contrary to the method of programming according to the example embodiment of FIG. 7, wherein an alternating current may be applied to the inverter type antifuse circuit, a direct current (DC) is supplied in the conventional programming method of FIG. 6, thereby requiring a voltage greater than 4V for programming. Also, comparatively a fewer number of electrons are trapped in a STI region in the conventional method.

According to the example embodiment shown in FIG. 5, the PMOS transistor P1 may function as the antifuse device. As a result, the capacitor C1, shown in FIG. 4, may not be required in the inverter type antifuse circuit of FIG. 5.

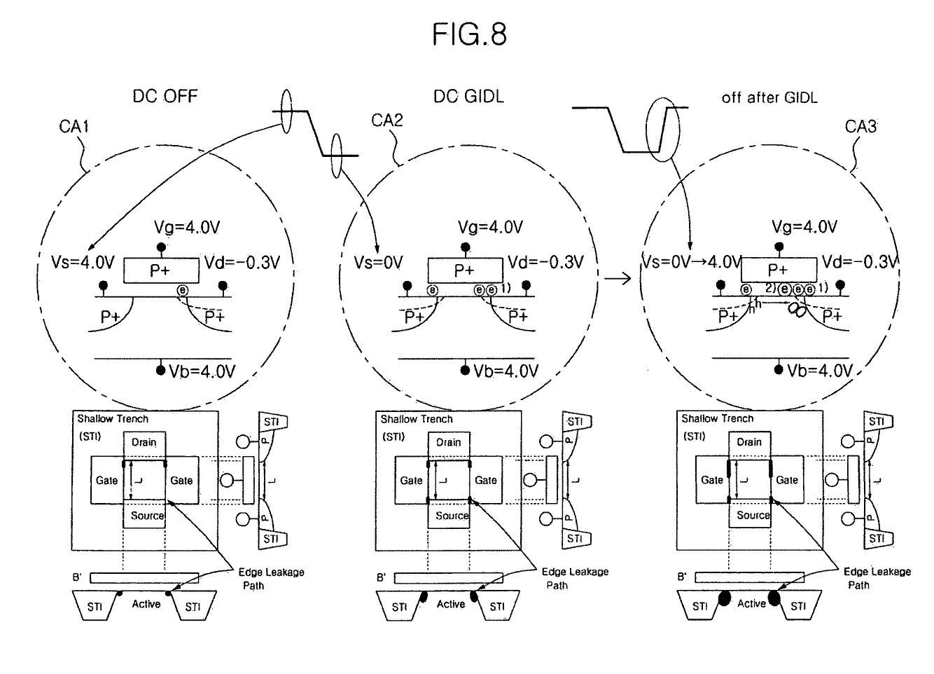

FIG. 8 compares a trapping effect observed in the STI electron trap due to the example programming method shown in FIG. 7 with a trapping effect observed in the STI electron trap due to the conventional programming method.

In FIG. 8, a first case CA1 shows electron trapping using a DC bias, as a result of the conventional programming method of FIG. 6. The second case CA2 and the third case CA3 illustrate electron trapping using an AC pulse, as a result of the programming method according to the example embodiment of FIG. 7.

In FIG. 8, gate-induced drain leakage (GIDL) is observed by applying around 0V to a source of the PMOS transistor, as in the second case CA2, and then applying an increased source voltage of around 4V, as in the third case CA3. As a result, a large number of electrons are accelerated and trapped in the STI region near the drain. During this time, the gate is maintained at about 4V, the drain at about −0.3V, and a body voltage Vb is maintained at about 4V.

In the first case CA1, the amount of electrons trapped in the STI region in the drain periphery is small and therefore it is difficult to utilize the PMOS transistor as a fuse device. As illustrated, during fuse programming using a DC bias scheme a voltage of around 4.0V is applied to a gate, a source and a body of the PMOS transistor. A voltage of around −0.3V is applied to a drain of the PMOS transistor. As such, a voltage difference between the gate and source of PMOS transistor is around 0V and a voltage difference between the gate and drain is around 4.3V. As a result, gate induced drain leakage (GIDL) effect is observed in a depletion region in the periphery of the drain and a weak current Ioff is generated. However, a hole, produced at the source, may not be accelerated with sufficient energy towards the drain by the source voltage (Vs≈4V). This may result in poor electron-hole recombination. In the second case CA2, 0V is applied to source, and then source voltage increases to 4V, as in the third case CA3. As a result, greater number of electrons are trapped in the STI region.

In the second case CA2, illustrating a condition before the application of the AC pulse, the gate and body are applied a voltage of approximately 4.0V. The source is applied a voltage of approximately 0V and the drain is applied a voltage of around −0.3V. Under such a bias condition, voltage difference between the gate and source is 4V, and voltage difference between the gate and drain is 4.3V. As a result, a GIDL effect is observed in the source and drain peripheries and a relatively greater amount of Ioff current flows. In the third case CA3, indicating the application of AC pulse, the source voltage is increased to around 4V. Accordingly, holes moving from the source terminal to the drain terminal are accelerated, which causes electron-hole pair generation in the drain periphery, resulting in increased amount of electrons in the STI region.

Accordingly, the high frequency low voltage pulse forms an electron trap in the STI region. During fuse programming, the PMOS transistor is in an OFF state and the electrons, generated as a result of gate-induced drain leakage (GIDL), are accelerated in the direction of the drain terminal and are trapped in the STI region.

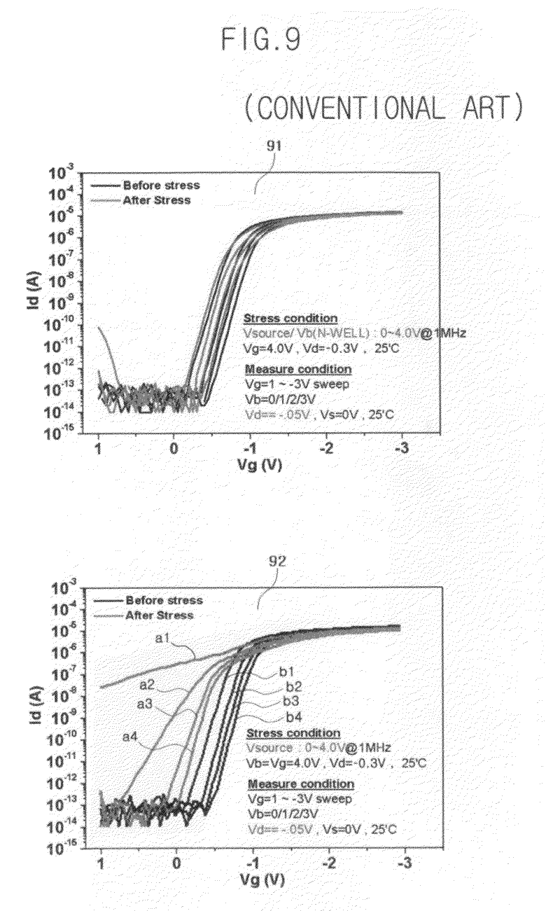

FIG. 9 compares the voltage-current (VI) characteristics of the PMOS transistor P1 of FIG. 5 programmed according to the example method of FIG. 7 (graph 92) with the VI characteristics of a PMOS transistor programmed according to the conventional programming method of FIG. 6 (graph 91). As shown in FIG. 9, the horizontal axis represents a gate voltage and the vertical axis represents a drain current. The bias and measurement conditions are also indicated on graphs 91 and 92. As is seen, the number of electrons trapped in the STI electron trap, according to the example embodiment (graph 92), is higher than the number of electron trapped in the conventional art STI electron trap (graph 91) even for similar voltage conditions. It can also be seen that the amount of electrons trapped increases with increase in frequency of the voltage applied at the source.

Referring to graph 92, curve b1 represents a VI characteristic of PMOS transistor P1 of FIG. 7 prior to electron trapping in the STI region or, in other words, prior to fuse programming. In this case, when the gate voltage Vg is around 0V or lower, current flows to the drain and the PMOS transistor P1 is turned ON. The VI characteristics of such a PMOS transistor P1 change to the characteristics indicated in curve a1 upon fuse programming. Both the curves a1 and b1 are obtained for somewhat similar bias and measurement conditions. Namely, gate voltage Vg is varied between approximately 1V to −3V, the body of the PMOS transistor P1 is applied a voltage Vb of around 0V, a drain as applied a voltage Vd of around −0.05V and a source is applied a voltage Vs of around 0V. As is seen, after fuse programming (curve a1), the PMOS transistor P1 is turned ON even when the gate voltage Vg is greater than 1V.

Graph 92 of FIG. 9 also illustrates the VI characteristics of the PMOS transistor P1 under a variety of stress conditions. In one instance, the body and the gate of the PMOS transistor P1 are each applied a voltage of around 4V, the drain is maintained a voltage of around −0.3V and a pulse of approximately 4V and a frequency of about 1 MHz is applied to the source terminal. As a result of application of such an AC high frequency pulse, GIDL effect is observed at the drain and electrons get trapped into the STI region and fuse programming is achieved.

In another stress condition, wherein the body is applied a voltage Vb of 1V, the VI characteristics of PMOS transistor P1 change from as indicated in curve b2 to curve a2. Herein, curve b2 indicates the VI characteristics of transistor P1 prior to fuse programming. In this case, the PMOS transistor P1 is turned ON and displays the characteristics of a fuse device when the gate voltage Vg is approximately 0.5V or greater.

Similarly, upon fuse programming, the VI characteristics of the PMOS transistor P1 of FIG. 7 change, from as indicated in curves b3 and b4, to as indicated by curves a3 and a4, respectively. The curves a3 and a4 indicate the VI characteristics when the bulk voltage Vb of the PMOS transistor P1 is around 2V and 3V, respectively. The remaining measurement conditions, Vd, Vg and Vs, are similar to those for curve a 1. As is seen, from curves a3 and a4, the PMOS transistor P1 exhibits characteristics of a fuse device when the gate voltage Vg is greater than 0V.

Accordingly, it is seen from graph 92, the PMOS transistor P1 has superior turn-on characteristics after fuse programming. As is seen in graph 91, there is an insignificant change in the turn-on characteristics before and after the fuse programming.

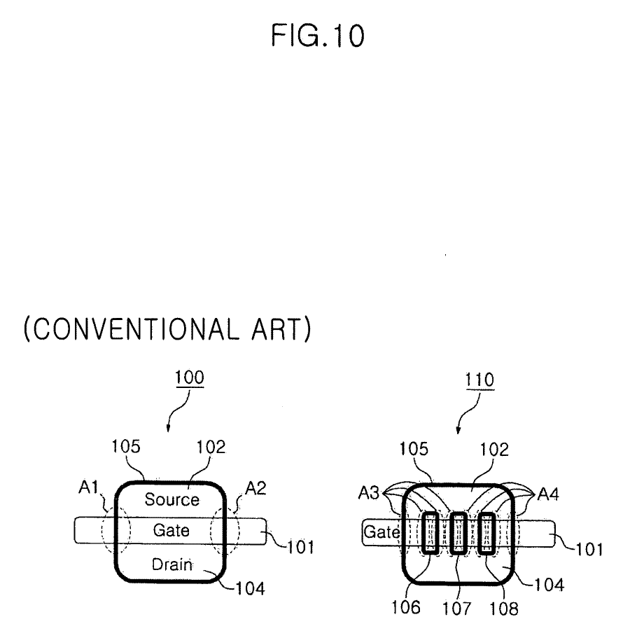

FIG. 10 illustrates a STI structure 100 of a PMOS transistor according to conventional art and STI structure 110 of a PMOS transistor according to example embodiments. With reference to the STI structure 110 in FIG. 10, a plurality of sub-STI regions 106, 107 and 108 are formed in the channel region in addition to a main STI region 105 to improve a trapping efficiency of the PMOS transistor P1. As is seen in FIG. 10, an STI structure 110 has three internal sub-STI regions 106, 107 and 108 in addition to the main STI region 105. As a result, the STI structure 110 may have an increased trap area as compared to the STI structure 100. Additionally, the STI structure 110 of FIG. 10 may not need supporting peripheral circuits, for example, an amplification circuit, for an improved performance. Accordingly, the antifuse device, according to example embodiments, may be implemented as a simple inverter circuit. In FIG. 10, reference numbers 101, 102, and 104 represent a gate, source and drain structure, respectively.

Unlike the device in conventional art, the antifuse circuit according to example embodiments may not require a fuse box or fuse device. Furthermore, the antifuse circuit according to example embodiments uses a leakage current between drain and source by inducing the STI trap of PMOS transistor, thereby trapping electrons using a relatively low voltage.

Example embodiments having thus been described, it will be obvious that the same may be varied in many ways. Such variations are not to be regarded as a departure from the intended spirit and scope of example embodiments, and all such modifications as would be obvious to one skilled in the art are intended to be included within the scope of the following claims. For example, it will be obvious to one of ordinary skills in the art to apply the teachings of the example embodiments to other volatile memories, for example, pseudo SRAM, PRAM and the like.

What is claimed is:

1. An antifuse circuit of an inverter type comprising:
a PMOS transistor, a gate terminal of the PMOS transistor coupled to a drive power voltage terminal and a source terminal of the PMOS transistor coupled to an anti-pad terminal,
wherein, during a fuse programming operation, the PMOS transistor is turned off and the source terminal of the PMOS transistor receives a pulse signal, and
wherein the fuse programming operation is performed using a shallow trench isolation (STI) trap scheme and is based on a gate-induced drain leakage current; and
an NMOS transistor, a drain terminal of the NMOS transistor coupled to a drain of the PMOS transistor, a source terminal of the NMOS transistor coupled to a ground voltage, and a gate terminal of the NMOS transistor coupled to a program control signal.

2. The antifuse circuit of claim 1, wherein the pulse signal is an alternating current (AC) pulse of a low voltage of around 4V or less.

3. The antifuse circuit of claim 1, wherein the pulse signal is a low voltage pulse signal varying from about 0V to about 4V and having a frequency of about 1 MHz.

4. The antifuse circuit of claim 2, wherein the low voltage AC pulse has a frequency from about 1 MHz to several GHz.

5. The antifuse circuit of claim 1, wherein a plurality of sub-STI regions are formed in a channel region of the PMOS transistor.

6. The antifuse circuit of claim 5, wherein the plurality of sub-STI regions include at least two sub-STI regions.

7. The antifuse circuit of claim 1, wherein the drive power voltage terminal is applied a voltage lower than an internal operating power voltage.

8. The antifuse circuit of claim 1, wherein the program control signal is at least one of an address signal and selection signal.

9. A semiconductor device including the antifuse circuit of claim 1.

10. A method of programming an antifuse circuit of an inverter type, the method comprising:
turning off a PMOS transistor of the antifuse circuit;
applying an alternating current (AC) pulse signal to a source terminal of the PMOS transistor; and
trapping a plurality of electrons in a shallow trench isolation (STI) region of the PMOS transistor.

11. The method of programming of claim 10, wherein electron trapping is due to gate-induced drain leakage.

12. The programming method of claim 10, wherein applied AC pulse signal is of a low voltage that varies from about 0V to about 4V and has a frequency of about 1 MHz.

13. The programming method of claim 10, wherein turning off the PMOS transistor includes applying a voltage lower than an internal operating power voltage to a gate terminal of the PMOS transistor.
